(19) United States
(12) Patent Application Publication
(10) Pub. No.: US 2026/0305111 A1
(43) Pub. Date: Oct. 1, 2026

(54) Display Device

(71) Applicant: LG Display Co., Ltd., Seoul (KR)

(72) Inventors: Jae Young Oh, Paju-si (KR); Ah Rum Sohn, Paju-si (KR); Eun Mi Cho, Paju-si (KR)

(21) Appl. No.: 19/423,934

(22) Filed: Dec. 17, 2025

(30) Foreign Application Priority Data
Dec. 30, 2024 (KR) 10-2024-0199569

(51) Int. Cl. H10K 59/38; H10K 59/80; H10K 59/88

(52) U.S. Cl. CPC H10K 59/38; H10K 59/873; H10K 59/8792; H10K 59/88

(57) ABSTRACT

The display device includes a display panel comprising a substrate layer; a circuit layer disposed on the substrate layer; a light-emitting element layer disposed on the circuit layer; an encapsulation layer disposed on the light-emitting element layer; and a color filter layer disposed on the encapsulation layer. The color filter layer includes a black matrix including a plurality of openings and a plurality of color filters disposed in the plurality of openings. The plurality of openings include a plurality of main openings overlapping light-emitting regions of light-emitting elements disposed in the light-emitting element layer, and a plurality of dummy openings disposed adjacent to the plurality of main openings.

### CROSS-REFERENCE TO RELATED APPLICATION

This application claims priority to and the benefit of Korean Patent Application No. 10-2024-0199569, filed on Dec. 30, 2024, the disclosure of which is incorporated herein by reference in its entirety.

### BACKGROUND

### Field

The present embodiments relate to a display panel and a display device including the same.

### Discussion of Related Art

A display device is widely used as a display screen for a variety of electronic devices, such as a mobile communication terminal, an electronic notebook, an e-book, a portable multimedia player (PMP), a navigation system, an ultra-mobile PC (UMPC), a mobile phone, a tablet personal computer (PC), a watch phone, an electronic pad, a wearable device, a portable information device, a vehicle control display device, a television, a notebook computer, and a monitor.

The display device may include a cover glass that is exposed to the outside, and a functional layer patterned and disposed in a regular shape on a lower portion of a cover glass. In this case, external light may be reflected by the patterned functional layer and cause moire phenomenon (hereinafter referred to as “moire”). As a result, moire may increase the reflected visibility, which may degrade the display quality for the user. Here, reflected visibility may refer to the degree to which light is reflected from the display device and perceived by the user's eyes.

Accordingly, there is a need for a display device that may prevent or minimize the occurrence of moire.

### SUMMARY

Embodiments of the present disclosure provide a display panel capable of preventing or minimizing the occurrence of moire, and a display device including the same.

Objectives to be solved by embodiments are not limited to the objectives described above, and objectives which are not described above will be clearly understood by those skilled in the art from the following descriptions.

A display device according to an embodiment of the present disclosure includes: a display panel comprising: a substrate layer; a circuit layer disposed on the substrate layer; a light-emitting element layer disposed on the circuit layer; an encapsulation layer disposed on the light-emitting element layer; and a color filter layer disposed on the encapsulation layer, wherein the color filter layer includes a black matrix including a plurality of openings and a plurality of color filters disposed in the plurality of openings, and the plurality of openings include a plurality of main openings overlapping light emitting regions of light-emitting elements disposed in the light-emitting element layer and a plurality of dummy openings disposed adjacent to the plurality of main openings.

A display device according to an embodiment of the present disclosure includes: a display panel comprising: a substrate layer; a circuit layer disposed on the substrate layer; a light-emitting element layer disposed on the circuit layer; an encapsulation layer disposed on the light-emitting element layer; and a color filter layer disposed on the encapsulation layer, wherein the color filter layer includes a black matrix including a plurality of openings and a plurality of color filters disposed in the plurality of openings, and the plurality of color filters include a plurality of main color filters overlapping light-emitting regions of light-emitting elements of the light-emitting element layer and a plurality of dummy color filters disposed adjacent to the plurality of main color filters.

Embodiments according to the present disclosure may prevent or minimize the occurrence of moire by disposing a dummy opening in addition to the opening used as a path through which light is emitted. Accordingly, the display device may reduce the reflected visibility through the dummy opening, thereby improving the display quality of the display device.

Embodiments according to the present disclosure may prevent or minimize the occurrence of moire by providing various embodiments regarding the shape, position, and arrangement relationship of dummy openings with main openings, thereby improving the design freedom of the display device.

Embodiments according to the present disclosure may implement a compact display device by arranging touch wires in a color filter layer. Accordingly, embodiments according to the present disclosure may improve the display device in terms of thinness and light weight.

Various useful advantages and effects of the embodiments are not limited to the above-described contents and will be more easily understood from descriptions of the specific embodiments.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display device according to one embodiment of the present disclosure;

FIG. 2 is a cross-sectional view schematically illustrating a display panel according to one embodiment of the present disclosure;

FIG. 3 is a cross-sectional view illustrating a cross-sectional structure of a pixel region disposed in a display area in the display panel according to one embodiment of the present disclosure;

FIGS. 4A to 4C are plan views illustrating the formation process of a color filter layer disposed in the display panel according to one embodiment of the present disclosure;

FIG. 5 is a cross-sectional view illustrating an arrangement relationship between a light-emitting element, a black matrix, and a color filter taken along lines I-I′ of FIG. 4C;

FIGS. 6A to 6D are diagrams illustrating various embodiments of shapes of dummy openings disposed in the display panel according to one embodiment of the present disclosure; and

FIG. 7 is a cross-sectional view illustrating a cross-sectional structure of a pixel region disposed in the display panel according to another embodiment of the present disclosure.

### DETAILED DESCRIPTION OF EXEMPLARY EMBODIMENTS

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

In the description for the embodiments, the first, second, etc. are used to describe various components, but these components are not limited by these terms. These terms are only used to distinguish one component from another. Therefore, the first component mentioned below may be a second component within the technical spirit of the present disclosure.

Throughout the specification, the same reference numerals refer to the same component.

The features of each of the various embodiments may be combined or combined with one another, in whole or in part, and various technical interlocking and driving may be possible, and each of the embodiments may be implemented independently of each other or in conjunction with each other.

Recently, the importance of a display device as a visual information transmission medium has been further emphasized in information-oriented society, and display devices are being improved to meet requirements, such as low power consumption, reduction of thickness, weight reduction, high definition, high efficiency, and the like.

The display device may include a functional layer patterned and disposed on a lower portion of a cover glass. Accordingly, the reflected light by the functional layer may form moire. For example, as the functional layer is patterned, the reflected light by the functional layer may also be patterned. And, due to the interference phenomenon of the patterned reflected light, the reflected light may form moire. In this case, the location of the occurrence of moire may change depending on the viewing angle of the display device. Here, the functional layer may be a color filter, an anode electrode, or the like.

The color filter may be patterned to correspond to a light-emitting region from which light is externally emitted and may be formed of a material having a predetermined reflectance. As a result, the reflected light reflected by the color filter may be patterned. Here, the light-emitting region may be an area in which light is externally emitted from the light-emitting element of the display panel, and a plurality of light-emitting regions may be formed to correspond to each of the plurality of light-emitting elements. For example, two light-emitting regions may be formed on the display panel to correspond to two light-emitting elements, respectively, and two color filters may be disposed on the two light-emitting elements to correspond to the two light-emitting regions, respectively. In addition, moire may be formed by a mutual interference phenomenon between the reflected light reflected by the respective two color filters. In this case, moire may be formed at a boundary (or a specific position) between the reflected light beams.

Further, the reflected light may be formed by the anode electrode. In addition, moire may be formed by a mutual interference phenomenon between the reflected light by the anode electrode and the reflected light by the color filters.

Accordingly, in the display device according to an embodiment of the present disclosure, separate dummy openings may be formed adjacent to main openings of the black matrix corresponding to the light-emitting regions, and color filters may be disposed in the dummy openings. Therefore, the reflected light from the color filters disposed in the dummy openings interferes with (or suppresses) the patterning of the reflected light from the color filters disposed in the main openings, thereby reducing the reflection visibility.

Therefore, since moire may be formed by the reflected light from the color filters arranged in the main openings, the display device according to the embodiment of the present disclosure may prevent or minimize the formation of moire using the dummy openings. Here, the term “adjacent” may include being arranged with a predetermined separation distance or being arranged in contact.

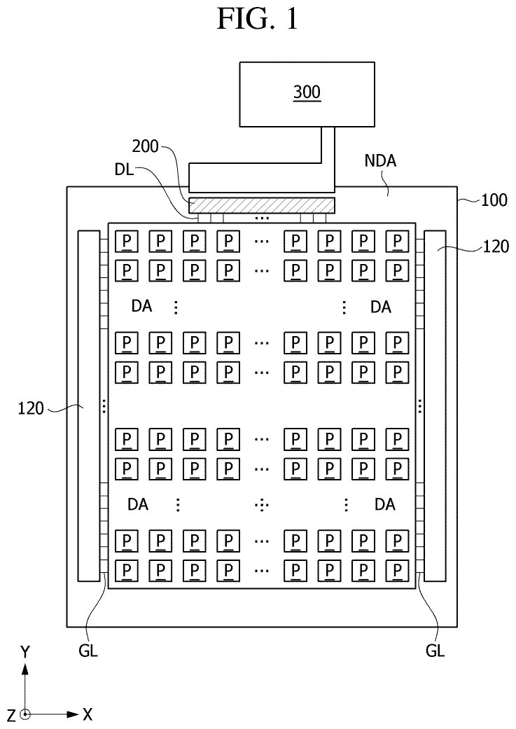

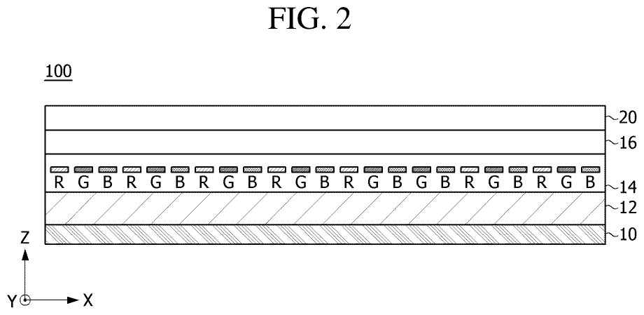

FIG. 1 is a diagram illustrating a display device according to one embodiment of the present disclosure. FIG. 2 is a cross-sectional view schematically illustrating a display panel according to one embodiment of the present disclosure.

Referring to FIGS. 1 and 2, the display device according to one embodiment of the present disclosure may include a display panel 100 and a case (not shown) that protects the display panel 100. The display device may include optical devices such as an image sensor (or camera), a proximity sensor, a white light illumination element, an optical element for facial recognition, and the like. For example, the optical device may include at least one of an image sensor, a proximity sensor, an illuminance sensor, a gesture sensor, a motion sensor, a fingerprint recognition sensor, and a biometric sensor.

The display panel 100 may implement the display of information, video, and/or an image provided to a user. For example, the display panel 100 may include a display area DA that implements the display of information, video, and/or an image, and a non-display area NDA that surrounds the display area DA.

The display area DA may be an area where a video is displayed. The display area DA may include a plurality of pixels P. Each of the plurality of pixels P may be composed of a plurality of sub-pixels. A plurality of light-emitting elements may be arranged in each of the plurality of sub-pixels. The plurality of light-emitting elements may be configured differently depending on the type of display device. For example, if the display device is an inorganic light-emitting display device, the light-emitting element may be a light-emitting diode (LED), a micro light-emitting diode (micro LED), or a mini light-emitting diode (mini LED), but embodiments of the present specification are not limited thereto. For example, if the display device is an organic light-emitting display device, the light-emitting element may be an organic light-emitting diode (OLED).

The non-display area NDA may be an area where no video is displayed. Various wires, circuits, and the like may be arranged in the non-display area NDA for driving the plurality of pixels P of the display area DA. For example, various wire and driver circuits may be mounted in the non-display area NDA, and a pad to which an integrated circuit, a printed circuit, and the like are connected may be arranged in the non-display area NDA, but embodiments of the present specification are not limited thereto.

The driver circuit may be a data driver circuit and/or a gate driver circuit, but embodiments of the present specification are not limited thereto. Wires configured to transmit control signals for controlling the driver circuits may be arranged in the display panel 100. For example, the control signals may include various timing signals including a clock signal, an input data enable signal, and synchronization signals, but embodiments of the present specification are not limited thereto. In this case, the control signals may be received through the pad. For example, link wires for transmitting signals may be arranged in the non-display area NDA. For example, driving components such as a flexible circuit board and a printed circuit board may be connected to the pad.

According to the present specification, the non-display area NDA may include a bending area. Here, the bending area may be a bendable area. In this case, the remaining area of the display panel 100, excluding the bending area, may be in a flat state. In addition, the pad may be arranged on the non-display area NDA.

The display panel 100 may have a width in the X-axis direction, a length in the Y-axis direction, and a thickness in the Z-axis direction. Here, the width and length of the display panel 100 may be set to various design values depending on application fields of the display device. In addition, the X-axis direction may mean a width direction or a horizontal direction, the Y-axis direction may mean a longitudinal direction or a vertical direction, and the Z-axis direction may mean a vertical direction, a stacking direction, or a thickness direction. Here, the X-axis direction, the Y-axis direction, and the Z-axis direction may be perpendicular to each other, but may also mean different directions that are not perpendicular to each other. Each of the X-axis direction, the Y-axis direction, and the Z-axis direction may be described as one of a first direction, a second direction, and a third direction. Further, the plane extended in the X-axis direction and the Y-axis direction may mean a horizontal plane.

The display panel 100 may include a substrate layer 10, a circuit layer 12 disposed on the substrate layer 10, a light-emitting element layer 14 disposed on the circuit layer 12, an encapsulation layer 16 disposed on the light-emitting element layer 14, and a color filter layer 20 disposed on the encapsulation layer 16.

The substrate layer 10 may be formed of an insulating material or a material having flexibility. For example, the substrate layer 10 may be made of glass, metal, or plastic, but is not limited thereto.

The substrate layer 10 may include the display area DA and the non-display area NDA. The display area DA and the non-display area NDA are not limited to being described only with respect to the substrate layer 10 but may be described across the entire display device.

The circuit layer 12 may include a pixel circuit connected to wirings such as data lines, gate lines, and power lines, a gate driver connected to the gate lines, and the like. Further, the circuit layer 12 may include transistors implemented with thin film transistors (TFTs) and circuit elements such as capacitors or the like. Here, the wirings and circuit elements of the circuit layer 12 may be implemented with a plurality of insulating layers, two or more metal layers separated with the insulating layer interposed therebetween, and an active layer including a semiconductor material.

The light-emitting element layer 14 may include a light-emitting element driven by a pixel circuit. Here, the light-emitting element may be implemented with an organic light emitting diode (OLED). The OLED may include an organic compound layer formed between an anode electrode and a cathode electrode. The organic compound layer includes a hole injection layer (HIL), a hole transport layer (HTL), an emission layer (EML), an electron transport layer (ETL), and an electron injection layer (EIL), but is not limited thereto. When a voltage is applied to an anode electrode and a cathode electrode of the OLED, the holes passing through the hole transport layer (HTL) and the electrons passing through the electron transport layer (ETL) may be moved to the light emitting layer (EML) to form excitons and emit visible light from the light emitting layer (EML).

The light-emitting element layer 14 may be covered by a protective film (not shown), and the protective film may be covered by an encapsulation layer 16. Here, the protective film may have a structure in which organic films and inorganic films are alternately stacked. In this case, the inorganic film may block penetration of moisture or oxygen. In addition, the organic film may planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 may be effectively blocked.

The encapsulation layer 16 covers the light-emitting element layer 14 so as to seal the circuit layer 12 and the light-emitting element layer 14. Here, the encapsulation layer 16 may have a multi-insulation film structure in which the organic film and the inorganic film are alternately stacked. In this case, the inorganic film blocks penetration of moisture or oxygen. In addition, the organic film planarizes the surface of the inorganic film. When the organic film and the inorganic film are stacked in multiple layers, the movement path of moisture or oxygen is longer than that of a single layer, so that the penetration of moisture/oxygen affecting the light-emitting element layer 14 may be effectively blocked.

The color filter layer 20 may be formed on the encapsulation layer 16. The color filter layer 20 may include red, green, and blue color filters. The color filter layer 20 may further include a black matrix pattern. The color filter layer 20 may absorb a portion of the wavelength of light reflected from the circuit layer 12, thereby replacing the role of a polarizing plate and enhancing color purity.

The color filter layer 20 may include an organic film covering the color filter and the black matrix pattern. The extended portion of the organic film may cover the inorganic film residue or the substrate layer 10 in the bezel region of the display panel 100, i.e., the edge region.

Metal wire patterns forming capacitance of touch sensors may be disposed in the color filter layer 20. In this case, the black matrix pattern may cover the metal wire patterns. Here, the touch sensors may be capacitive touch sensors that sense touch input based on changes in capacitance before and after touch input.

A cover glass omitted from the drawing may be adhered to the color filter layer 20.

The display device according to embodiment of the present disclosure may include the display panel 100 having a pixel array arranged on a screen, and a display panel driver, etc.

The pixel array of the display panel 100 may include data lines DL, gate lines GL intersecting the data lines DL, and pixels P connected to the data lines DL and gate lines GL and arranged in a matrix, as shown in FIG. 1.

The pixel array may be divided into a circuit layer 12 and a light-emitting element layer 14, as shown in FIG. 2. Then, a touch sensor array may be arranged on the light-emitting element layer 14. Here, each of the pixels of the pixel array may include two to four sub-pixels. Each of the sub-pixels may include a pixel circuit arranged in the circuit layer 12.

Each of the sub-pixels of the display area DA may include a pixel circuit. The pixel circuit may include a driving element to supply current to the light-emitting element (OLED), a plurality of switching elements to sample a threshold voltage of the driving element and switch a current path of the pixel circuit, a capacitor to maintain a gate voltage of the driving element, etc. In this case, the pixel circuit may be arranged below the light-emitting element.

The display panel driver may write pixel data of an input image into the pixels P. The pixels may be interpreted as a pixel group including a plurality of sub-pixels.

The display panel driver may include a data driver that supplies a data voltage of pixel data to the data lines DL and a gate driver 120 that sequentially supplies gate pulses to the gate lines GL. Further, the data driver may be integrated into the drive IC 200, as shown in FIG. 1. In addition, the display panel driver may further include a touch sensor driver omitted from the drawings.

The drive IC 200 may be bonded on the display panel 100. The drive IC 200 receives pixel data of an input image and a timing signal from a host system 300, supplies a data voltage of the pixel data to pixels, and synchronizes the data driver and the gate driver 120.

The drive IC 200 may be connected to the data lines DL through data output channels to supply data voltages of pixel data to the data lines DL. The drive IC 200 may output a gate timing signal for controlling the gate driver 120 through gate timing signal output channels.

The gate driver 120 may include a shift register formed on a circuit layer of the display panel 100 together with a pixel array. The shift register of the gate driver 120 may sequentially supply gate signals to the gate lines GL under the control of the timing controller. The gate signal may include a scan pulse and an EM (emission) pulse of an emission signal.

The host system 300 may be implemented with an application processor (AP). The host system 300 may transmit pixel data of an input image to the drive IC 200 through a mobile industry processor interface (MIPI). The host system 300 may be connected to the drive IC 200 through a flexible printed circuit (FPC), for example.

Meanwhile, the display panel 100 may be implemented with a flexible panel applicable to a flexible display.

The flexible panel may be made of a so-called “plastic OLED panel”. The plastic OLED panel may include a back plate and a pixel array on an organic thin film adhered on the back plate. A touch sensor array may be formed over the pixel array.

The back plate may be a polyethylene terephthalate (PET) substrate. The pixel array and the touch sensor array may be formed on the organic thin film. The back plate may block moisture permeation toward the organic thin film so that the pixel array is not exposed to humidity.

The organic thin film may be a polyimide (PI) substrate. A multi-layered buffer film may be formed on the organic thin film with an insulating material. Further, the circuit layer 12 and the light-emitting element layer 14 may be stacked on the organic thin film.

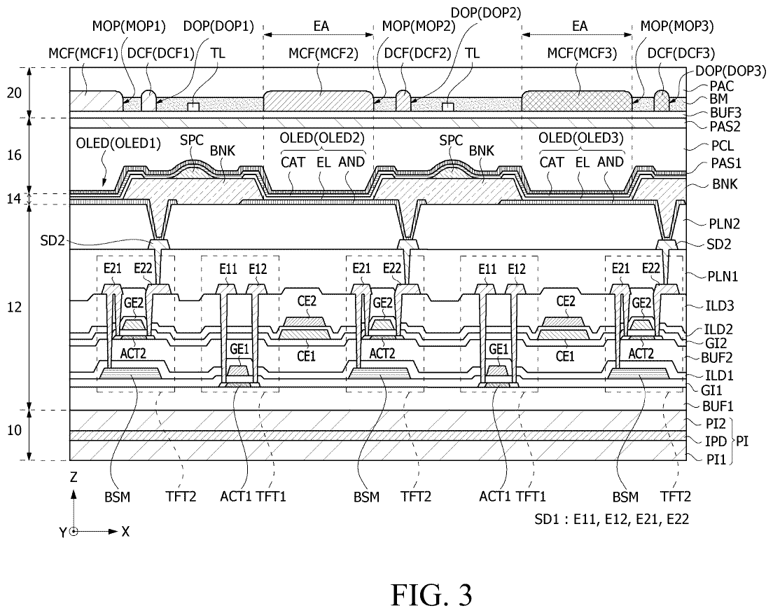

FIG. 3 is a cross-sectional view conceptually illustrating a cross-sectional structure of a pixel area disposed in a display area in a display panel according to one embodiment of the present invention. Here, it should be noted that the cross-sectional structure of the pixel area is not limited to that of FIG. 3. In FIG. 3, TFT may represent a driving element of the pixel circuit. In detail, TFT1 may be a first TFT that is one of LTPS TFTs disposed in the display area, and TFT2 may be a second TFT that is one of oxide TFTs disposed in the display area.

Referring to FIG. 3, a plurality of pixel circuits and wires connected to the pixel circuits may be disposed in the display area DA of the display panel 100. Here, the pixel circuits of the display area may include a pixel circuit of a red sub-pixel driving a red light-emitting element, a pixel circuit of a green sub-pixel driving a green light-emitting element, and a pixel circuit of a blue sub-pixel driving a blue light-emitting element. Further, the pixel circuits may be separated into a plurality of circuit areas along the X-axis direction of the display panel 100 within the display area DA.

The substrate PI may include first and second sub-substrates PI1 and PI2. In addition, an inorganic film IPD may be formed between the first sub-substrate PI1 and the second sub-substrate PI2. In this case the inorganic film IPD may block moisture permeation. Here, since the substrate PI may be formed of polyimide, it may be referred to as a PI substrate, and the first and second sub-substrates PI1 and PI2 may be referred to as first and second PI sub-substrates. The substrate PI corresponds to the substrate layer 10 as described previously.

The first buffer layer BUF1 may be formed on the second sub-substrate PI2. The first buffer layer BUF1 may be formed of a multi-layered insulating layer in which two or more oxide layers SiO₂ and nitride layers SiNx are stacked. A first semiconductor layer is formed on the first buffer layer BUF1. The first semiconductor layer may include a polysilicon semiconductor layer patterned in a photolithography process. The first semiconductor layer may include a first active pattern ACT1 of polysilicon semiconductor forming a semiconductor channel in the first TFT TFT1.

A first gate insulating layer GI1 is deposited on the first buffer layer BUF1 to cover the first active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer may include a single metal layer patterned in a photolithography process or metal patterns in which two or more metal layers are stacked. The first metal layer may include the gate electrode GE1 of the first TFT TFT1 and a light shield pattern BSM under the second TFT TFT2.

A first interlayer insulating layer ILD1 is formed on the first gate insulating layer GI1 to cover the patterns of the first metal layer. The first interlayer insulating layer ILD1 may include an inorganic insulating material. A second buffer layer BUF2 is formed on the first interlayer insulating layer ILD1. The second buffer layer BUF2 may include a single layer or a multi-layer inorganic insulating material.

A second semiconductor layer is formed on the second buffer layer BUF2. The second semiconductor layer may include an oxide semiconductor layer patterned in a photolithography process. The second semiconductor layer may include a second pattern ACT2 of oxide semiconductor forming a semiconductor channel in the second TFT TFT2. A second gate insulating layer GI2 may be deposited on the second buffer layer BUF2 to cover the second active pattern ACT2 of the second semiconductor layer. The second gate insulating layer GI2 may include a single or multi-layered inorganic insulating material. A second metal layer may be formed on the second gate insulating layer GI2. The second metal layer may be insulated from the second semiconductor layer by the second gate insulating layer GI2.

The second metal layer may include a single metal layer patterned in a photolithography process or metal patterns in which two or more metal layers are stacked. The second metal layer may include a gate electrode GE2 of the second TFT TFT2 and a lower capacitor electrode CE1.

A second interlayer insulating layer ILD2 may be formed on the second gate insulating layer GI2 to cover the patterns of the second metal layer. The second interlayer insulating layer ILD2 may include a single layer or a multi-layer inorganic insulating material. A third metal layer may be formed on the second interlayer insulating layer ILD2. The third metal layer may be insulated from the second metal layer by the second interlayer insulating layer ILD2.

The third metal layer may include a single metal layer patterned in a photolithography process or metal patterns in which two or more metal layers are stacked. The third metal layer may include an upper capacitor electrode CE2. The capacitor Cst of the pixel circuit may be composed of the upper capacitor electrode CE2, the lower capacitor electrode CE1, and a dielectric layer therebetween, that is, the second interlayer insulating layer ILD2.

A third interlayer insulating layer ILD3 covering the patterns of the third metal layer may be formed on the second interlayer insulating layer ILD2. The third interlayer insulating layer ILD3 may include a single layer or a multi-layer inorganic insulating material. A fourth metal layer may be formed on the third interlayer insulating layer ILD3. The fourth metal layer may be insulated from the third metal layer by the third interlayer insulating layer ILD3.

The fourth metal layer may include a single metal layer patterned in a photolithography process or metal patterns in which two or more metal layers are stacked. The fourth metal layer may include first and second electrodes E11 and E12 of the first TFT TFT1 and first and second electrodes E21 and E22 of the second TFT TFT2, and may be a first metal pattern SD1 of FIG. 3. The first and second electrodes E11 and E12 of the first TFT TFT1 may be connected to a first active pattern ACT1 through a first contact hole passing through the first gate insulating layer GI1, the first interlayer insulating layer ILD1, the second buffer layer BUF2, the second gate insulating layer GI2, the second interlayer insulating layer ILD2 and the third interlayer insulating layer ILD3. The first and second electrodes E21 and E22 of the second TFT TFT2 may be connected to a second active pattern ACT2 through a second contact hole passing through the insulating layers GI2, ILD2 and ILD3. The first electrode E21 of the second TFT TFT2 may be connected to the light shield pattern BSM through a third contact hole passing through the first interlayer insulating layer ILD1, the second buffer layer BUF2, the second gate insulating layer GI2, the second interlayer insulating layer ILD2 and the third interlayer insulating layer ILD3. Here, a strong electric field may be generated in the metal pattern (i.e. E11 to E22) of the fourth metal layer due to voltages swinging between a gate-on voltage and a gate-off voltage with a large voltage difference.

A first planarization layer PLN1 may cover the pattern (i.e. E11 to E22) of the fourth metal layer. The first planarization layer PLN1 may thickly cover the display area DA of the circuit layer 12 with an organic insulating material. When the first planarization layer PLN1 is applied on the circuit layer 12, the organic insulating material may flow to the edge of the display panel 100 and cover the side surface of the circuit layer 12.

A fifth metal layer may be formed on the first planarization layer PLN1. The fifth metal layer may be insulated from the fourth metal layer by the first planarization layer PLN1. The fifth metal layer may include a single metal layer patterned in a photolithography process or metal patterns in which two or more metal layers are stacked. The fifth metal layer may include a second metal pattern SD2 connecting the light-emitting element to the second TFT TFT2. The second metal pattern SD2 may be connected to the second electrode E22 of the second TFT TFT2 through a fourth contact hole penetrating the first planarization layer PLN1.

A second planarization layer PLN2 may be formed on the first planarization layer PLN1 to cover the metal patterns of the fifth metal layer. The second planarization layer PLN2 may thickly cover the display area DA of the circuit layer 12 with an organic insulating material. A sixth metal layer may be formed on the second planarization layer PLN2. The second planarization layer PLN2 may planarize the surface on which the sixth metal layer is formed.

The sixth metal layer may include a single metal layer patterned in a photolithography process or metal patterns in which two or more metal layers are stacked. The pattern of the sixth metal layer may include an anode electrode AND of the light emitting element. The anode electrode AND may be in contact with the second metal pattern SD2 connected to the second TFT TFT2 of the pixel circuits through the fifth contact hole penetrating the second planarization layer PLN2.

In the light emitting element layer 14, a bank BNK may be formed on the second planarization layer PLN2 to cover the edge of the anode electrode AND. In this case, the bank BNK may be formed in a pattern that divides a light emitting area (or an opening area) from which light is emitted from each pixel to the outside. Accordingly, the bank BNK may be referred to as a pixel-defining film. The bank BNK may be patterned in a photolithography process by including an organic insulating material having photosensitivity. Further, a spacer SPC having a predetermined height may be formed on the bank BNK. In this case, the bank BNK and the spacer SPC may be integrated with the same organic insulating material. Further, the spacer SPC secures a gap between a fine metal mask (FMM) and the anode electrode AND so that the FMM is not in contact with the anode electrode AND during a deposition process of the light emitting element formed of an organic compound.

A seventh metal layer used as a cathode electrode CAT of the light-emitting element may be formed on the bank BNK and an organic compound layer EL. The seventh metal layer may be connected between sub-pixels in the display area DA. Here, the organic compound layer EL may be referred to as a light emitting layer or an electroluminescent layer.

The encapsulation layer 16 may include multiple insulating layers covering the cathode electrode CAT of the light emitting device. The multiple insulating layers may include a first inorganic insulating layer PAS1 covering the cathode electrode CAT, a thick organic insulating layer PCL covering the first inorganic insulating layer PAS1, and a second inorganic insulating layer PAS2 covering the thick organic insulating layer PCL.

The color filter layer 20 may be disposed on the encapsulation layer 16.

The color filter layer 20 may include a third buffer layer BUF3 covering the second inorganic insulating layer PAS2, a black matrix BM disposed on the third buffer layer BUF3 and including a plurality of openings, a color filter CF placed in the opening of the black matrix BM, and a color filter insulating layer PAC covering the black matrix BM and the color filter CF. Here, the third buffer layer BUF3 may be a color filter buffer layer. The color filter insulating layer PAC may include an organic insulating material. In addition, the opening of the black matrix BM may include a plurality of main openings MOP and a plurality of dummy openings DOP.

The third buffer layer BUF3 may include a single-layered or multi-layered inorganic insulating material. For example, the third buffer layer BUF3 may be formed of a multi-layered insulating film in which two or more oxide films (SiO₂) and nitride films (SiNx) are stacked.

The black matrix BM may be formed of a material having high optical density (OD). Therefore, the black matrix BM may absorb or block light.

The black matrix BM may overlap the bank BNK of the light-emitting element layer 14.

The black matrix BM may be a pattern including a plurality of main openings MOP and a plurality of dummy openings DOP. For example, a plurality of main openings MOP and a plurality of dummy openings DOP may be formed in the black matrix BM to have a predetermined regularity. Accordingly, the black matrix BM may be provided as a pattern defined by the plurality of main and dummy openings.

The plurality of main openings MOP and the plurality of dummy openings DOP may be provided as through-holes formed to penetrate the black matrix BM in the Z-axis direction, but is not necessarily limited to this. For example, since the main openings MOP need to act as passages for light emitted by the light-emitting element (OLED) to be emitted to the outside, the main openings MOP may be provided as through-holes. However, since the color filters CF placed in the dummy openings DOP need to interfere with (or suppress) the patterning of reflected light from the color filters CF placed in the main openings MOP, the dummy openings DOP may be provided as concave grooves formed on the top surface of the black matrix BM, which do not penetrate the black matrix.

A main opening MOP may overlap the light-emitting region EA of the light-emitting element OLED disposed in the light-emitting element layer 14. Accordingly, light formed by the light-emitting element OLED may be emitted to the outside through the light-emitting region EA. In this case, the main opening MOP may be formed in a shape corresponding to the light-emitting region EA.

A dummy opening DOP may be disposed adjacent to the main opening MOP. As shown in FIG. 3, the dummy opening DOP may be spaced apart from the main opening MOP by a predetermined spacing, but is not necessarily limited thereto. For example, one side of the dummy opening DOP may be disposed in contact with the main opening MOP. When the dummy opening DOP is spaced apart from the main opening MOP, the material of the black matrix BM may be disposed between the main opening MOP and the dummy opening DOP.

The dummy opening DOP may overlap the bank BNK of the light-emitting element layer 14. Light formed in the light-emitting element OLED may be emitted to the outside through the dummy opening DOP provided as the through-hole, but the present disclosure is not limited thereto.

By adjusting the thickness of the thick organic insulating layer PCL and the third buffer layer BUF3 disposed on the light-emitting element OLED, as well as the separation distance between the main opening MOP and the dummy opening DOP, light from the light-emitting element OLED may either be emitted externally through the dummy opening DOP or prevented from being emitted. For example, when the light of the light-emitting element OLED is emitted externally through the dummy opening DOP where the color filter CF is arranged, the light passing through the dummy opening DOP may be utilized to improve the luminance of the display device. Also, when light from the light-emitting element OLED is not emitted externally through the dummy opening DOP where the color filter CF is arranged, the light passing through the main opening MOP may not be affected by light passing through the dummy opening DOP.

Further, by disposing a portion of the material of the black matrix BM at the lower portion of the dummy opening DOP, light may be prevented in advance from exiting through the dummy opening DOP. As a result, the dummy opening DOP may be provided as a groove formed in the top surface of the black matrix BM. Accordingly, the dummy opening DOP may be provided as a concave groove formed on the top surface of the black matrix BM, which does not penetrate the black matrix BM. Therefore, the display device according to one embodiment of the present disclosure includes the groove-shaped dummy opening DOP, which may prevent in advance the emission of light through the dummy opening DOP.

The dummy opening DOP may be formed in a different shape and/or size than the main opening MOP. For example, when viewing the display panel 100 from the Z-axis, the main opening MOP may be formed in a rectangular shape, and the dummy opening DOP may be formed in a circular, triangular, and polygonal shape. Further, when viewing the display panel 100 from the Z-axis, the main opening MOP may be formed in a square shape, and the dummy opening DOP may be formed in a rectangular shape having a different size from the main opening MOP. As a result, the color filter CF of the dummy opening DOP formed in a different shape and/or size from the main opening MOP may further suppress (or interfere with) the patterning of reflected light by the color filter CF disposed in the main opening MOP. Here, the reflected light by the color filter CF disposed in the main opening MOP may be a first reflected light, a first pattern light, or a main reflected light. The reflected light by the color filter CF disposed in the dummy opening DOP may be a second reflected light, a second pattern light, or a dummy reflected light.

The color filter CF may be disposed to corresponding to the light-emitting region EA of the light-emitting element OLED and may have any one of red, green, and blue color. For example, the color filter CF may include a red color filter, a green color filter, and a blue color filter to match each color implemented in a sub-pixel, that is, the light-emitting element OLED.

The color filter CF may be disposed in the main opening MOP of the black matrix BM. The color filter CF disposed in the main opening MOP may overlap the light-emitting region EA in the Z-axis direction. The color filter CF may also be disposed in the dummy opening DOP. For example, when a red color filter is disposed in one of the two main openings MOP arranged adjacent to each other, a red color filter may be disposed in the dummy opening DOP arranged adjacent to the red color filter. Here, the display device according to an embodiment of the present disclosure exemplifies a case where the color filter CF is disposed in the dummy opening DOP, but is not necessarily limited thereto. For example, a material having a predetermined reflectance and being different from the color filter CF may be disposed in the dummy opening DOP to interfere with (or suppress) the patterning of reflected light reflected by the color filter CF disposed in the main opening MOP.

The color filter insulating layer PAC may be disposed on the black matrix BM and the color filter CF. Also, the color filter insulating layer PAC may be formed of an organic insulating material such as polyimide or acrylic resin.

The color filter layer 20 may further include a touch wire TL disposed in the inside of the black matrix BM. Accordingly, the display device according to one embodiment of the present disclosure may implement the display panel 100 that is more compact in size than a display device that includes a separate touch sensor layer.

The touch wire TL may be formed in a predetermined pattern on the third buffer layer BUF3. In this case, the touch wire TL may be disposed on the third buffer layer BUF3 without interfering with the light-emitting region EA.

The black matrix BM may be disposed on the touch wire TL. That is, the black matrix BM may cover the touch wire TL. Accordingly, the black matrix BM may improve display quality of the display device by preventing external light from being reflected from the touch wire TL. In addition, as the touch wire TL is patterned, the reflected light from the touch wire TL may form moire, but the black matrix BM covering the touch wire TL may prevent the occurrence of moire due to the light reflection from the touch wire TL.

An eighth metal layer used as the touch wire TL may be disposed on the third buffer layer BUF3 and may overlap the bank BNK. The eighth metal layer may include a single layer metal patterned in a photolithography process or metal pattern in which two or more metal layers are stacked. For example, the touch wire TL may include a bridge metal composed of metal wire patterns and a touch sensor metal to form the capacitance of the touch sensors.

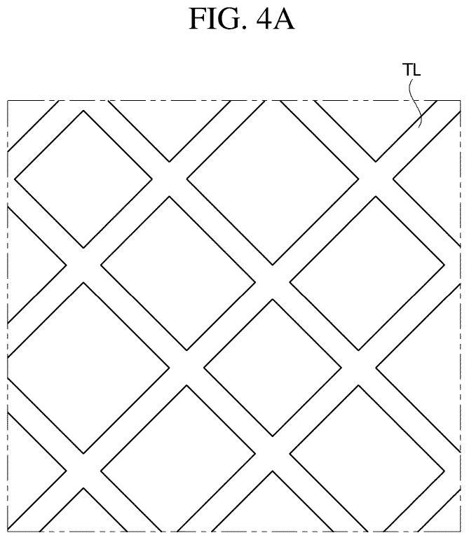

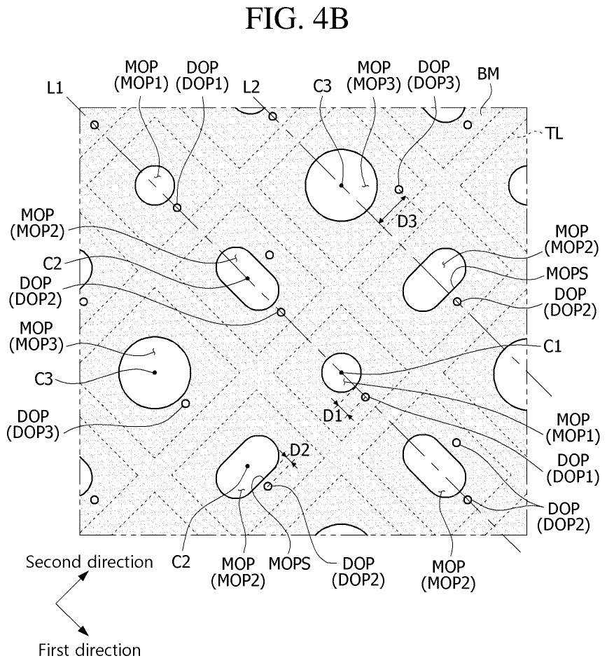

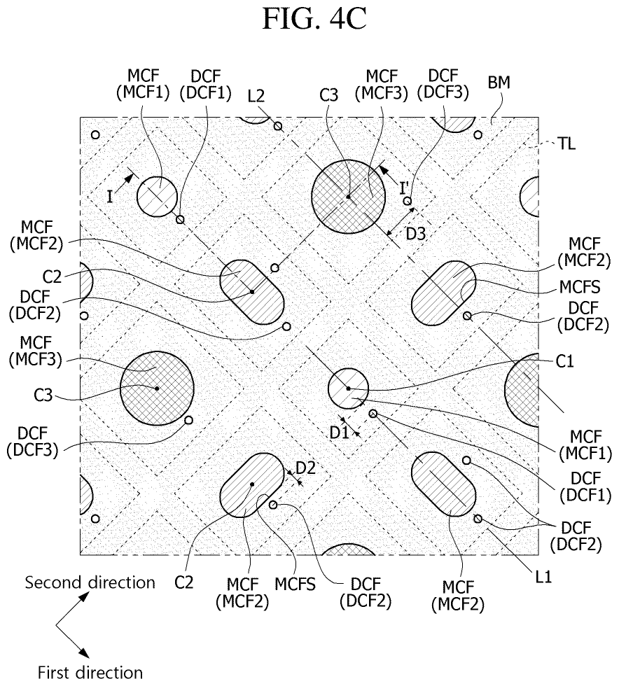

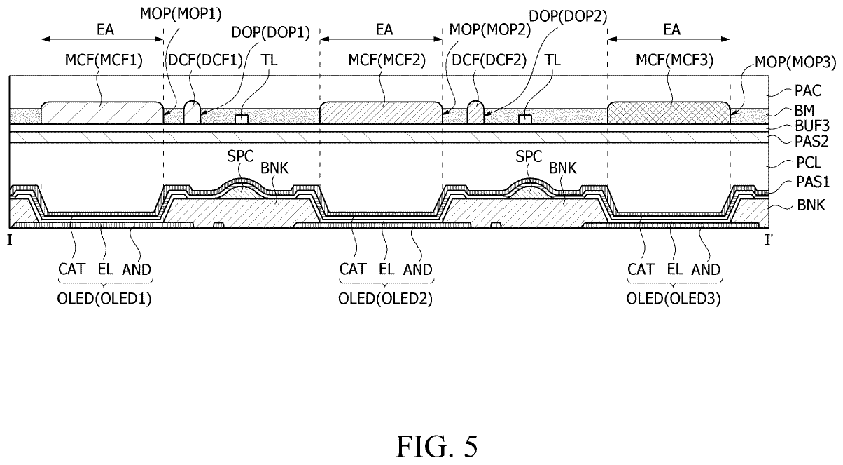

FIGS. 4A to 4C are plan views illustrating a process of forming the color filter layer disposed in the display panel according to one embodiment of the present disclosure. For example, FIG. 4A is a plan view illustrating the touch wire TL disposed on the third buffer layer BUF3. For example, FIG. 4B is a plan view illustrating the black matrix BM disposed on the touch wire TL. For example, FIG. 4C is a diagram illustrating the color filter CF disposed in the opening of the black matrix BM. FIG. 5 is a cross-sectional view illustrating an arrangement relationship between the light-emitting element, the black matrix, and the color filter taken along line I-I′ of FIG. 4C. For example, FIG. 5 may illustrate a first main color filter MCF1 disposed to correspond to a first light-emitting element OLED1, a second main color filter MCF2 disposed to correspond to a second light-emitting element OLED2, and a third main color filter MCF3 disposed to correspond to a third light-emitting element OLED3. Further, FIG. 5 may illustrate a first main opening MOP1 of the black matrix BM in which the first main color filter MCF1 is disposed, a second main opening MOP2 of the black matrix BM in which the second main color filter MCF2 is disposed, and a third main opening MOP3 of the black matrix BM in which the third main color filter MCF3 is disposed. In addition, FIG. 5 may illustrate a first dummy opening DOP1 disposed adjacent to the first main opening MOP1 of the black matrix BM, a second dummy opening DOP2 disposed adjacent to the second main opening MOP2 of the black matrix BM, and a third dummy opening DOP3 disposed adjacent to the third main opening MOP3 of the black matrix BM. In this case, a first dummy color filter DCF1 may be disposed in the first dummy opening DOP1, a second dummy color filter DCF2 may be disposed in the second dummy opening DOP2, and a third dummy color filter DCF3 may be disposed in the third dummy opening DOP3.

Referring to FIGS. 3, 4A, and 5, the touch wire TL may be disposed on the third buffer layer BUF3. In this case, in consideration of the plurality of light-emitting regions EA of the display panel 100, the touch wire TL may be disposed in a lattice shape having a plurality of holes on the third buffer layer BUF3. As shown in FIG. 5, the distance from the main opening MOP to the touch wire TL adjacent to the main opening MOP is greater than the distance from the main opening MOP to the dummy opening DOP adjacent to the main opening MOP. That is, the distance from the main opening MOP to the dummy opening DOP adjacent to the main opening MOP is smaller than the distance from the main opening MOP to the touch wire TL adjacent to the main opening MOP.

Referring to FIGS. 3, 4B, 4C, and 5, the black matrix BM may be disposed to cover the touch wire TL. In this case, the black matrix BM may include the main openings MOP and the dummy openings DOP, and the main openings MOP and the dummy openings DOP may be disposed to overlap the holes of the touch wire TL formed in a lattice shape.

The main openings MOP and the dummy openings DOP may be provided as through-holes penetrating the black matrix BM. In this case, the main openings MOP and the dummy openings DOP may not overlap the touch wire TL in the Z-axis direction.

The main openings MOP and the dummy openings DOP may have different sizes. For example, the size of the main openings MOP may be larger than that of the dummy openings DOP.

The main openings MOP may be formed in a predetermined shape and/or size.

Since the shape and/or size of the main opening MOP may be determined according to the color implemented by the light-emitting element OLED, the shapes and/or sizes of the main openings MOP disposed corresponding to the colors of the light-emitting elements OLED may be different from each other. For example, the main opening MOP may include the first main opening MOP1, the second main opening MOP2, and the third main opening MOP3. Here, the first main opening MOP1 may be disposed to correspond to the first light-emitting element OLED1 implementing red color. The second main opening MOP2 may be disposed to correspond to the second light-emitting element OLED2 implementing green color. In addition, the third main opening MOP3 may be disposed to correspond to the third light-emitting element OLED3 implementing blue color. In this case, shapes and/or sizes of the first main opening MOP1, the second main opening MOP2, and the third main opening MOP3 may be different from each other.

The color filter CF may include the main color filter MCF disposed in the main opening MOP and the dummy color filter DCF disposed in the dummy opening DOP. In addition, the main color filter MCF and the dummy color filter DCF may be formed in different shapes and/or sizes.

The main color filter MCF and the dummy color filter DCF may be disposed to be spaced apart from each other at a predetermined interval by the material of the black matrix BM. Also, the main color filter MCF may be disposed on the light-emitting region EA, and the dummy color filter DCF may overlap the bank BNK.

The main color filter MCF may include the first main color filter MCF1 disposed in the first main opening MOP1, the second main color filter MCF2 disposed in the second main opening MOP2, and the third main color filter MCF3 disposed in the third main opening MOP3. Also, the dummy color filter DCF may include the first dummy color filter DCF1 disposed in the first dummy opening DOP1, the second dummy color filter DCF2 disposed in the second dummy opening DOP2, and the third dummy color filter DCF3 disposed in the third dummy opening DOP3. In this case, the first main color filter MCF1 and the first dummy color filter DCF1 may be color filters of the same color. Also, the second main color filter MCF2 and the second dummy color filter DCF2 may be color filters of the same color. Also, the third main color filter MCF3 and the third dummy color filter DCF3 may be color filters of the same color.

Since the main color filter MCF is disposed in the patterned main opening MOP, the main color filter MCF may also be patterned. And, since the patterned main color filter MCF is formed of a material having a predetermined reflectance, the external light reflected from the main color filter MCF may form moire.

When the main color filter MCF includes one side formed in a straight line, the frequency of moire occurrence may increase. Here, one side of the main color filter MCF formed in a straight line may be one side of the main color filter MCF disposed in the main opening MOP. For example, since the main opening MOP may include at least one side MOPS formed in a straight line, one side of the main color filter MCF disposed within the main opening MOP may also include one side MCFS formed in a straight line. As shown in FIG. 4C, a side surface of the second main color filter MCF2 disposed in the second main opening MOP2 may have a straight line shape. In this case, as the length of the one side MCFS of the main color filter MCF formed in a straight line shape becomes longer, the frequency of moire occurrence may further increase.

Therefore, the display device according to an embodiment of the present disclosure may more effectively prevent or minimize the occurrence of moire by arranging the dummy opening DOP adjacent to one side MOPS of the main opening MOP formed in a straight line shape. That is, the display device according to the embodiment of the present disclosure may more effectively prevent or minimize the occurrence of moire by arranging the dummy color filter DCF adjacent to one side MCFS of the main color filter MCF formed in a straight line shape.

Since the main color filters MCF are formed to correspond to a plurality of light-emitting regions EA that implement different colors, the first main color filter MCF1, the second main color filter MCF2, and the third main color filter MCF3 may have different shapes and/or sizes.

Considering the prevention and minimization of the formation of moire by the main reflected light, the shape and/or size of the first dummy color filter DCF1, the second dummy color filter DCF2, and the third dummy color filter DCF3 may be formed to correspond to the shape and/or size of the first main color filter MCF1, the second main color filter MCF2, and the third main color filter MCF3, respectively. In this case, the shapes and/or sizes of the first dummy color filter DCF1, the second dummy color filter DCF2, and the third dummy color filter DCF3 may be different from each other, but are not limited thereto. For example, the first dummy color filter DCF1, the second dummy color filter DCF2, and the third dummy color filter DCF3 may have the same shape and/or size.

The first dummy opening DOP1 may be disposed at a first distance D1 from the first main opening MOP1, and the second dummy opening DOP2 may be disposed at a second distance D2 from the second main opening MOP2. In this case, the first distance D1 and the second distance D2 may be different. Accordingly, the first dummy color filter DCF1 may be disposed at the first distance D1 from the first main color filter MCF1, and the second dummy color filter DCF2 may be disposed at the second distance D2 from the second main color filter MCF2 that is different from the first distance D1. For example, the first distance D1 may be greater than the second distance D2, but the embodiment of the present disclosure is not limited thereto.

Accordingly, the display device according to an embodiment of the present disclosure may more effectively interfere with (or suppress) the patterning of reflected light from the main color filter MCF by setting the first distance D1 and the second distance D2 differently.

The first main opening MOP1 and the second main opening MOP2 may be disposed adjacent to each other along the first direction. Further, at least one dummy opening DOP may be disposed between the first main opening MOP1 and the second main opening MOP2. For example, two or more second dummy openings DOP2 may be disposed around the second main opening MOP2. Accordingly, at least one dummy color filter DCF may be disposed between the first main color filter MCF1 and the second main color filter MCF2, but the embodiment according to the present disclosure are not limited thereto. For example, there may be cases where a dummy opening DOP is not disposed between two main openings MOP arranged in a second direction, which is a different direction from the first direction. Accordingly, there may be cases where a dummy color filter DCF is not disposed between two main color filters MCF arranged in a second direction, which is a different direction from the first direction.

Referring to FIG. 4C, a dummy opening DOP may be disposed on an imaginary line connecting centers of two main openings MOP disposed adjacent to each other along the first direction. Accordingly, the dummy color filter DCF disposed between the two main color filters MCF disposed adjacent to each other along the first direction may be disposed on the imaginary line. For example, the second dummy opening DOP2 may be disposed on a first imaginary line L1 connecting a center C1 of the first main opening MOP1 and a center C2 of the second main opening MOP2. Accordingly, the second dummy color filter DCF2 may be disposed on the first imaginary line L1.

Therefore, the display device according to the embodiment of the present disclosure may interfere with (or suppress) the patterning of reflected light from the main color filter MCF by arranging the dummy color filter DCF on an imaginary line connecting the centers of the two adjacent main openings MOP.

In addition, a dummy opening DOP may be disposed to be spaced apart from an imaginary line connecting the centers of the two main openings MOP arranged adjacent to each other along the first direction. Accordingly, the dummy color filter DCF disposed in the dummy opening DOP may also be spaced apart from the imaginary line. For example, the third dummy opening DOP3 may be disposed to be spaced apart from a second imaginary second line L2 connecting the center C2 of the second main opening MOP2 and a center C3 of the third main opening MOP3. Accordingly, the third dummy color filter DCF3 may be disposed to be spaced apart from the second imaginary line L2 by a third distance D3.

Depending on the viewing angle of the display panel 100, the occurrence of moire may vary. Accordingly, the display device according to an embodiment of the present disclosure arranges some dummy color filters DCF to be spaced apart from an imaginary line connecting the centers of two adjacent main openings MOP, thereby preventing or minimizing the occurrence of moire due to the viewing angle. In addition, the plurality of dummy color filters DCF may be disposed to be spaced apart from each other at different distances on an imaginary line connecting the centers of the adjacent main openings MOP. Accordingly, the formation of moire according to the viewing angle may be prevented or minimized. Consequently, the display device according to an embodiment of the present disclosure may prevent or minimize the occurrence of moire due to the viewing angle by irregularly positioning the plurality of dummy color filters DCF around the plurality of main color filters MCF. For example, some of the plurality of dummy color filters DCF may be positioned at different distances from the main color filter MCF or positioned apart from an imaginary line connecting the centers of the two adjacent main color filters MCF, thereby preventing or minimizing the occurrence of moire due to the viewing angle.

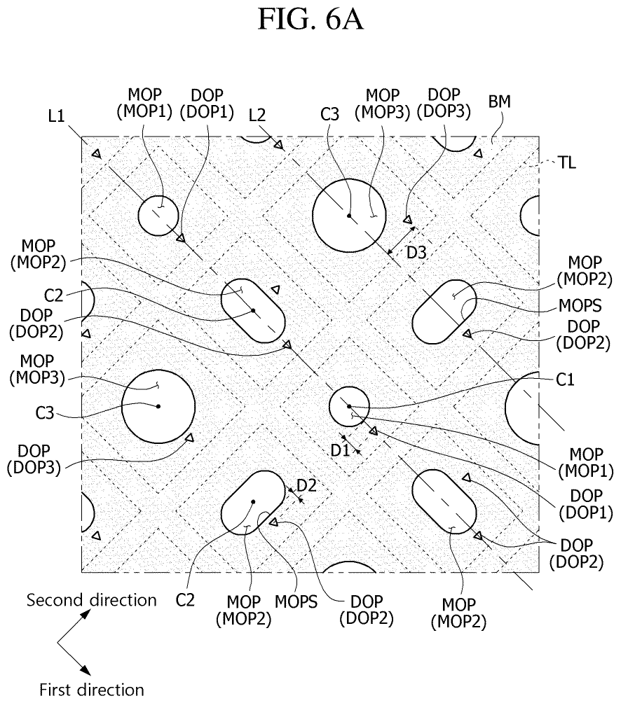

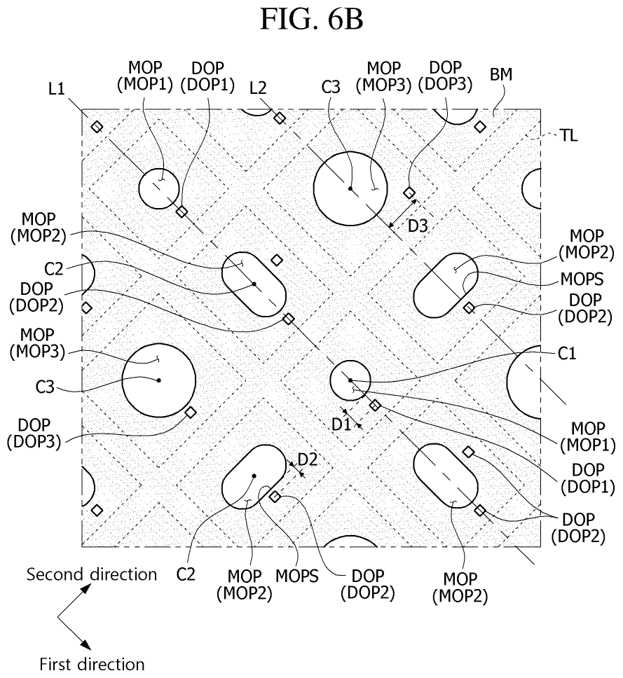

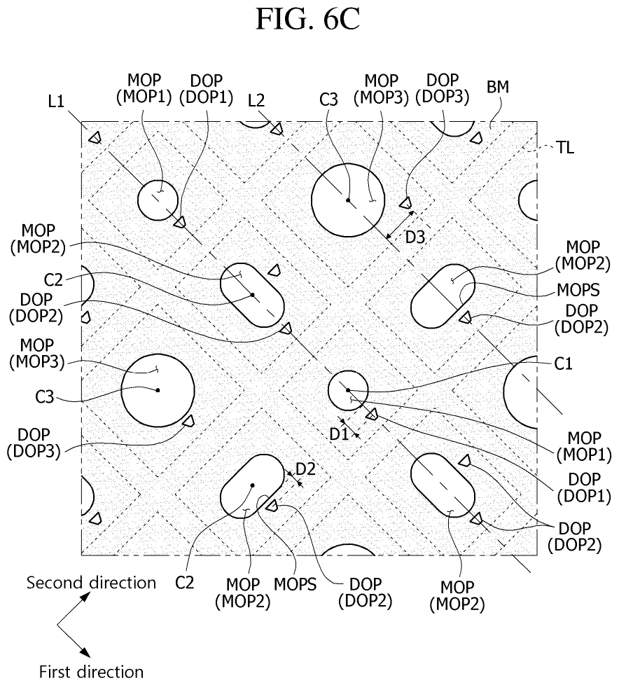

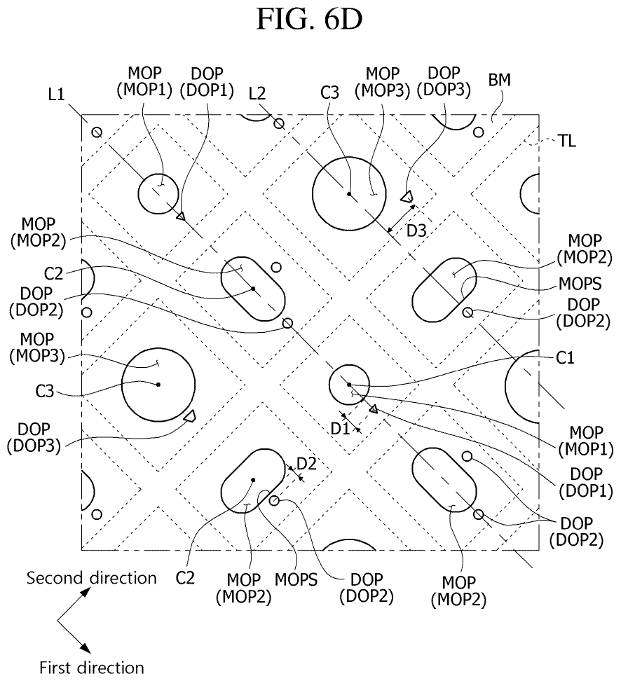

FIGS. 6A to 6D are diagrams illustrating various embodiments of a shape of a dummy opening disposed in the display panel according to one embodiment of the present disclosure. For example, FIG. 6A is a diagram illustrating the dummy opening DOP including a triangular shape. FIG. 6B is a diagram illustrating the dummy opening DOP including a rectangular shape. FIG. 6C is a diagram illustrating the dummy opening DOP including the trapezoidal shape. FIG. 6D is a diagram illustrating the dummy openings DOP including the triangular shape, the rectangular shape, and the trapezoidal shape.

Referring to FIGS. 6A to 6C, the dummy opening DOP may be formed in a triangular, rectangular, trapezoidal, or polygonal shape. In addition, dummy openings DOP formed in various shapes may be formed in various sizes. In addition, a plurality of dummy openings DOP may be located at a predetermined distance from the adjacent main opening MOP. In this case, the positions of the plurality of dummy openings DOP may be different relative to the adjacent main opening MOP.

Referring to FIG. 6D, the dummy openings DOP may include a first dummy opening DOP1 of a triangular shape disposed adjacent to the first main opening MOP1, a second dummy opening DOP2 of a circular shape disposed adjacent to the second main opening MOP2, and a third dummy opening DOP3 of a trapezoidal shape disposed adjacent to the third main opening MOP3. That is, the shape of the dummy openings DOP may vary depending on the corresponding main opening MOP.

Accordingly, the display device according to an embodiment of the present disclosure may provide various embodiments by varying the shape, size, distance, and position of the dummy opening DOP, and their combinations, thereby improving the degree of design freedom of the display device. For example, a plurality of dummy openings DOP may be formed in at least two different shapes among triangular, rectangular, trapezoidal, and polygonal shapes, and their distances and/or positions may also vary. In addition, the number of dummy openings DOP adjacent to the main opening MOP may also vary. For example, when the number of the first dummy opening DOP1 disposed adjacent to the first main opening MOP1 is one, the number of the second dummy opening DOP2 disposed adjacent to the second main opening MOP2 may be two. Accordingly, by varying the shapes, sizes, distances, positions, numbers, and their combinations of the dummy opening DOP, various embodiments may be provided, thereby further preventing or minimizing the formation of moire caused by the main reflected light.

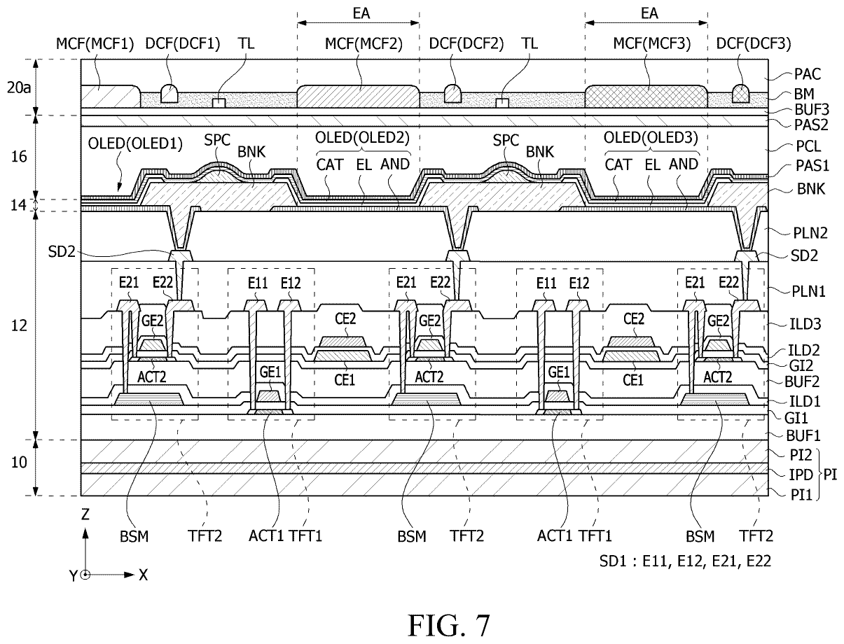

FIG. 7 is a cross-sectional view illustrating a cross-sectional structure of a pixel region disposed in the display panel according to another embodiment of the present disclosure.

Referring to FIG. 7, the display panel 100 may include the substrate PI (i.e. the substrate layer 10), the circuit layer 12 on the substrate PI, the light-emitting element layer 14 on the circuit layer 12, the encapsulation layer 16 on the light-emitting element layer 14, and a color filter layer 20a on the encapsulation layer 16. The substrate PI, the circuit layer 12, the light-emitting element layer 14, and the encapsulation layer 16 disposed in the display panel 100 are substantially the same as those of the pixel region of the display area DA with reference to FIG. 3, and thus the same reference numerals are assigned thereto, and redundant descriptions thereof may be omitted or simplified.

The color filter layer 20a may include a third buffer layer BUF3, a black matrix BM disposed on the third buffer layer BUF3, a color filter CF disposed in the opening of the black matrix BM, a touch wire TL disposed inside the black matrix BM, and a color filter insulating layer PAC covering the black matrix BM and the color filter CF. In this case, the opening of the black matrix BM may include a main opening MOP provided as a through-hole and a dummy opening DOP provided as a groove. Here, the groove may be formed concavely on the top surface of the black matrix BM, and may not penetrate the black matrix BM.

A dummy color filter DCF may be disposed in the dummy opening DOP provided as a groove. Accordingly, the black matrix BM may be disposed to overlap the lower portion of the dummy color filter DCF. For example, since the black matrix BM is disposed between the third buffer layer BUF3 and the dummy color filter DCF, the dummy color filter DCF may be spaced apart from the third buffer layer BUF3 by the black matrix BM.

Therefore, the display device according to the embodiment of the present disclosure may prevent light from being externally emitted in advance through the use of the dummy opening DOP provided in a groove shape.

A display device according to one or more configurations of the present specification may be described as follows.

A display device according to one or more embodiments of the present specification may include: a display panel comprising: a substrate layer; a circuit layer disposed on the substrate layer; a light-emitting element layer disposed on the circuit layer; an encapsulation layer disposed on the light-emitting element layer; and a color filter layer disposed on the encapsulation layer, wherein the color filter layer may include a black matrix including a plurality of openings and a plurality of color filters disposed in the plurality of openings, and the plurality of openings may include a plurality of main openings overlapping light-emitting regions of light-emitting elements disposed in the light-emitting element layer and a plurality of dummy openings disposed adjacent to the plurality of main openings.

According to one or more embodiments of the present specification, the plurality of dummy openings may overlap a bank of the light-emitting element layer.

According to one or more embodiments of the present specification, the plurality of color filters may include a plurality of main color filters disposed in the plurality of main openings and a plurality of dummy color filters disposed in the plurality of dummy openings.

According to one or more embodiments of the present specification, a material of the black matrix may be disposed between the plurality of main openings and the plurality of dummy openings.

According to one or more embodiments of the present specification, the plurality of main openings and the plurality of dummy openings may have different shapes and/or sizes from each other.

According to one or more embodiments of the present specification, the plurality of main openings may include a first main opening and a second main opening disposed adjacent to each other, and at least one of the plurality of dummy openings may be disposed between the first main opening and the second main opening.

According to one or more embodiments of the present specification, the plurality of dummy openings may include a first dummy opening disposed adjacent to the first main opening and a second dummy openings disposed adjacent to the second main opening, and the first dummy opening and the second dummy opening may have different shapes and/or sizes from each other.

According to one or more embodiments of the present specification, the plurality of color filters may include a first main color filter disposed in the first main opening and a second main color filter disposed in the second main opening, and the plurality of color filters may include a first dummy color filter disposed in the first dummy opening and a second dummy color filter disposed in the second dummy opening, wherein the color of the first dummy color filter may be the same as the color of the first main color filter, and the color of the second dummy color filter may be the same as the color of the second main color filter.

According to one or more embodiments of the present specification, the colors of the first main color filter and the second main color filter may be different from each other.

According to one or more embodiments of the present specification, the first main opening and the second main opening may have different shapes and/or sizes from each other.

According to one or more embodiments of the present specification, the first dummy opening may be disposed at a first distance from the first main opening, the second dummy opening may be disposed at a second distance from the second main opening, and the first distance and the second distance may be different from each other.

According to one or more embodiments of the present specification, at least one of the plurality of dummy openings may be disposed to be spaced apart from an imaginary line connecting the center of the first main opening and the center of the second main opening.

According to one or more embodiments of the present specification, the color filter layer may further include a touch wire disposed on the encapsulation layer, and the black matrix may cover the touch wires.

According to one or more embodiments of the present specification, the distance from one of the plurality of main openings to one of the plurality of dummy openings adjacent to the one of the plurality of main openings may be smaller than the distance from the one of the plurality of main openings to the touch wire adjacent to the one of the plurality of main openings.

According to one or more embodiments of the present specification, the touch wire may overlap a bank of the light-emitting element layer.

According to one or more embodiments of the present specification, the plurality of main openings and the plurality of dummy openings may be provided as through-holes.

According to one or more embodiments of the present specification, the plurality of main openings may be provided as through-holes, and the plurality of dummy openings may be provided as grooves which do not penetrate the black matrix.

A display device according to one or more configurations of the present specification may include a display panel comprising a substrate layer; a circuit layer disposed on the substrate layer; a light-emitting element layer disposed on the circuit layer; an encapsulation layer disposed on the light-emitting element layer; and a color filter layer disposed on the encapsulation layer, wherein the color filter layer includes a black matrix including a plurality of openings and a plurality of color filters disposed in the plurality of openings, and the plurality of color filters include a plurality of main color filters overlapping light-emitting region of light-emitting element disposed in the light-emitting element layer and a plurality of dummy color filters disposed adjacent to the plurality of main color filters.

According to one or more embodiments of the present specification, the plurality of dummy color filters may overlap a bank of the light-emitting element layer.

According to one or more embodiments of the present specification, the plurality of dummy color filters may be disposed adjacent to one sides of the plurality of main color filters formed in a linear shape.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel comprising:
a substrate layer;
a circuit layer disposed on the substrate layer;
a light-emitting element layer disposed on the circuit layer;
an encapsulation layer disposed on the light-emitting element layer; and
a color filter layer disposed on the encapsulation layer,
wherein the color filter layer includes a black matrix including a plurality of openings and a plurality of color filters disposed in the plurality of openings, and
the plurality of openings include a plurality of main openings overlapping light-emitting regions of light-emitting elements disposed in the light-emitting element layer and a plurality of dummy openings disposed adjacent to the plurality of main openings.

2. The display device of claim 1, wherein the plurality of dummy openings overlap a bank of the light-emitting element layer.

3. The display device of claim 1, wherein the plurality of color filters include a plurality of main color filters disposed in the plurality of main openings and a plurality of dummy color filters disposed in the plurality of dummy openings.

4. The display device of claim 1, wherein a material of the black matrix is disposed between the plurality of main openings and the plurality of dummy openings.

5. The display device of claim 1, wherein the plurality of main openings and the plurality of dummy openings have different shapes and/or sizes from each other.

6. The display device of claim 1, wherein:
the plurality of main openings include a first main opening and a second main opening disposed adjacent to each other, and
at least one of the plurality of dummy openings is disposed between the first main opening and the second main opening.

7. The display device of claim 6, wherein;
the plurality of dummy openings include a first dummy opening disposed adjacent to the first main opening and a second dummy opening disposed adjacent to the second main opening, and
the first dummy opening and the second dummy opening have different shapes and/or sizes from each other.

8. The display device of claim 7, wherein:
the plurality of color filters include a first main color filter disposed in the first main opening and a second main color filter disposed in the second main opening, and
the plurality of color filters include a first dummy color filter disposed in the first dummy opening and a second dummy color filter disposed in the second dummy opening, wherein a color of the first dummy color filter is the same as a color of the first main color filter, and a color of the second dummy color filter is the same as a color of the second main color filter.

9. The display device of claim 8, wherein the colors of the first main color filter and the second main color filter are different from each other.

10. The display device of claim 6, wherein the first main opening and the second main opening have different shapes and/or sizes from each other.

11. The display device of claim 9, wherein:
the first dummy opening is disposed at a first distance from the first main opening,
the second dummy opening is disposed at a second distance from the second main opening, and
the first distance and the second distance are different from each other.

12. The display device of claim 6, wherein at least one of the plurality of dummy openings are spaced apart from an imaginary line connecting a center of the first main opening and a center of the second main opening.

13. The display device of claim 1, wherein:
the color filter layer further includes a touch wire disposed on the encapsulation layer, and
the black matrix covers the touch wire.

14. The display device of claim 13, wherein a distance from one of the plurality of main openings to one the plurality of dummy openings adjacent to the one of the plurality of main openings is smaller than a distance from the one of the plurality of main openings to the touch wire adjacent to the one of the plurality of main openings.

15. The display device of claim 14, wherein the touch wire overlaps a bank of the light-emitting element layer.

16. The display device of claim 1, wherein the plurality of main opening and the plurality of dummy opening are provided as through-holes.

17. The display device of claim 1, wherein:
the plurality of main openings are provided as through-holes, and
the plurality of dummy openings are provided as grooves which do not penetrate the black matrix.

18. A display device comprising:
a display panel comprising:
a substrate layer;
a circuit layer disposed on the substrate layer;
a light-emitting element layer disposed on the circuit layer;
an encapsulation layer disposed on the light-emitting element layer; and
a color filter layer disposed on the encapsulation layer,
wherein the color filter layer includes a black matrix including a plurality of openings and a plurality of color filters disposed in the plurality of openings, and
the plurality of color filters include a plurality of main color filters overlapping light-emitting regions of light-emitting elements disposed in the light-emitting element layer and a plurality of dummy color filters disposed adjacent to the plurality of main color filters.

19. The display device of claim 18, wherein the plurality of dummy color filters overlap a bank of the light-emitting elements.

20. The display device of claim 19, wherein the plurality of dummy color filters are disposed adjacent to one sides of the plurality of main color filters formed in a straight line.
